(19) United States
(12) Patent Application Publication
(10) Pub. No.: US 2026/0239559 A1
(43) Pub. Date: Aug. 13, 2026

(54) AUTOMATIC FAN SETTING ADJUSTMENT

(71) Applicant: Aivres Systems Inc., San Jose, CA (US)

(72) Inventors: Mingduo KAO, New Taipei City (TW); Huei ming CHU, New Taipei City (TW)

(21) Appl. No.: 19/050,739

(22) Filed: Feb. 11, 2025

(51) Int. Cl. H05K 7/20; F04D 27/00

(52) U.S. Cl. CPC H05K 7/20209; F04D 27/004

(57) ABSTRACT

One or more embodiments of the present specification provide fan setting adjustment methods, apparatuses, and systems. At each of one or more time points, a temperature measurement is received from a temperature sensor. Based on the temperature measurement and as a determined fan setting, a fan setting for a printed circuit board component corresponding to the temperature sensor is determined. The fan setting for the printed circuit board component is transmitted to a fan corresponding to the printed circuit board component.

### BACKGROUND

Computing devices, such as servers, are widely used in a variety of fields. In areas such as artificial intelligence (AI) and big data, the need for computing devices is growing rapidly. Some computing devices include a large number of printed circuit board (PCB) components, or high-performance components (e.g., high-performance and/or requiring a large amount of power to perform their functions) such as processors and memory modules. For example, a computing device for AI applications can be configured to include one or more graphical processing units (GPUs). Storage servers can be configured to include one or more non-volatile memory express (NVMe) devices.

A large number of components, or powerful components may generate large amounts of heat. High temperatures can impact the performance of the printed circuit board and/or components. For example, higher temperatures can result in component degradation, reduced performance, increased power consumption, and system instability. Some computing devices use one or more fans on the printed circuit board to circulate air and promote heat dissipation/removal (i.e., cooling).

### SUMMARY

The present disclosure describes systems and techniques to automatically adjust a fan setting to impact the temperature in the environment of a printed circuit board (PCB) component.

In an implementation, a temperature measurement is received from a temperature sensor. A fan setting for a printed circuit board component corresponding to the temperature sensor is determined based on the temperature measurement and as a determined fan setting. The fan setting for the printed circuit board component is transmitted to a fan corresponding to the printed circuit board component.

The described subject matter can be implemented using a computer-implemented method; a non-transitory, computer-readable medium storing computer-readable instructions to perform the computer-implemented method; and a computer-implemented system comprising one or more computer memory devices interoperably coupled with one or more computers and having tangible, non-transitory, machine-readable media storing instructions that, when executed by the one or more computers, perform the computer-implemented method/the computer-readable instructions stored on the non-transitory, computer-readable medium.

The subject matter described in this specification can be implemented to realize one or more of the following advantages. Described systems and techniques can allow for air circulation and promote heat dissipation/removal in the environment of a PCB component on a PCB. In particular, as computing devices become more powerful (e.g., high-performance and/or requiring a large amount of power to perform their functions), the number, complexity, and density of components on PCBs increases. As the number, complexity, and density of components increases, overall power consumption and an amount of heat generated by the components increases. Without thermal management, the performance, reliability, and lifespan of the computing device may be negatively affected.

Some conventional thermal management systems do not adapt to dynamically changing workloads, e.g., periods of sudden increased or decreased processing. Some conventional thermal management systems set the same fan setting for all fans, which can result in unnecessary power consumption for some fans, high noise levels, and inefficient heat dissipation/removal (i.e., cooling). The described systems and techniques allow for independent and accurate targeting of the areas surrounding particular PCB components to achieve heat dissipation/removal. The described systems and techniques can ensure that one or more PCB components are maintained in their respective operating temperatures, which reduces the likelihood of performance issues due to overheating. System performance and stability is thus increased due to the precise and localized temperature adjustment for each of the PCB components.

The details of one or more implementations of the subject matter of this specification are set forth in the Detailed Description, the Claims, and the accompanying drawings. Other features, aspects, and advantages of the subject matter will become apparent to those of ordinary skill in the art from the Detailed Description, the Claims, and the accompanying drawings.

### DESCRIPTION OF DRAWINGS

FIG. 1 is a block diagram of a system for automatically adjusting a fan setting, according to an implementation of the present disclosure.

FIG. 2 is a diagram of an example process for automatically adjusting a fan setting, according to an implementation of the present disclosure.

FIG. 3 is a flowchart illustrating an example of a computer-implemented method for automatically adjusting a fan setting, according to an implementation of the present disclosure.

FIG. 4 is a block diagram illustrating an example of a computer-implemented system used to provide computational functionalities associated with described algorithms, methods, functions, processes, flows, and procedures, according to an implementation of the present disclosure.

Like reference numbers and designations in the various drawings indicate like elements.

### DETAILED DESCRIPTION

The following detailed description describes systems and techniques to automatically adjust a fan setting to impact the temperature of the environment of a printed circuit board (PCB) component and is presented to enable any person skilled in the art to make and use the disclosed subject matter in the context of one or more particular implementations. Various modifications, alterations, and permutations of the disclosed implementations can be made and will be readily apparent to those of ordinary skill in the art, and the general principles defined can be applied to other implementations and applications, without departing from the scope of the present disclosure. In some instances, one or more technical details that are unnecessary to obtain an understanding of the described subject matter and that are within the skill of one of ordinary skill in the art may be omitted so as to not obscure one or more described implementations. The present disclosure is not intended to be limited to the described or illustrated implementations, but to be accorded the widest scope consistent with the described principles and features.

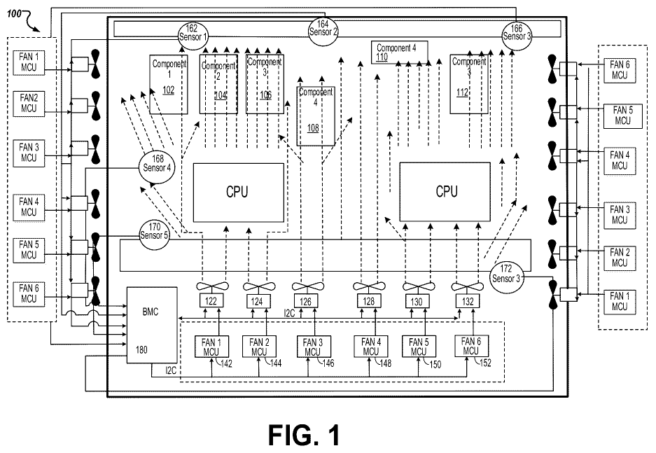

FIG. 1 is a block diagram of a system 100 for automatically adjusting a fan setting, according to an implementation of the present disclosure. The system 100 includes multiple PCB components such as PCB components 102, 104, 106, 108, 110, and 112. The PCB components are connected, e.g., mounted or soldered, onto the surface of the PCB. The PCB components can include, for example, diodes, transistors, integrated circuits (ICs), connectors, sensors, processors, accelerators, memory, etc. Processors can include, for example, central processing units (CPUs), graphics processing units (GPUs), multi-core processors, microprocessors, quantum processors, or a combination of these.

The system 100 includes multiple fans, such as the fan 122, 124, 126, 128, 130, and 132. Each of the fans corresponds to a PCB component. In some examples, each of the fans corresponds to a different PCB component. In some examples, at least two of the fans correspond to the same PCB component. In some examples, a fan can correspond to multiple PCB components. In the example of FIG. 1, the fan 122 corresponds to the component 102 and 104. The fan 124 corresponds to the component 106. The fan 126 corresponds to the component 108. The fan 128 corresponds to the component 110. The fan 130 corresponds to the component 110. The fan 132 corresponds to the component 112.

In some implementations, the fans can be located in different positions relative to the components. For example, in FIG. 1, the fans 122, 124, 126, 128, 130, and 132 are shown as being positioned below the components. In some examples, the fans can be positioned along the left or right side of the PCB.

In some implementations, the fans can be connected to the PCB using a fan mounting bracket at the bottom of the chassis. In some implementations, the fans can be connected to the PCB using one or more connectors, or connected directly to the PCB. The fans can be connected to the PCB using a fastening method such as screws, clips, or brackets. In some implementations, the fans can be powered through cables.

Airflow from each fan is directed at a corresponding PCB component(s) of the multiple PCB components. For example, FIG. 1 shows the example airflow for each fan directed at the one or more corresponding component(s).

The system 100 includes multiple microcontroller units (MCUs) such as the MCU 142, 144, 146, 148, 150, and 152. Each of the MCUs is configured to be connected to a corresponding fan of the multiple fans. For example, the MCU 142 is connected to the fan 122. The MCU 144 is connected to the fan 124, the MCU 146 is connected to the fan 126, the MCU 148 is connected to the fan 128, the MCU 150 is connected to the fan 130, and the MCU 152 is connected to the fan 132.

The system 100 includes multiple temperature sensors, such as the sensor 162, 164, 166, 168, 170, and 172. Each temperature sensor is configured to determine a temperature measurement at one or more time points. Each temperature sensor of the temperature sensors is configured to be connected to a corresponding MCU of the multiple MCUs. For example, the temperature sensor 162 is connected to the MCU 142. The temperature sensor 164 is connected to the MCU 144, the temperature sensor 166 is connected to the MCU 146, the temperature sensor 168 is connected to the MCU 148, the temperature sensor 170 is connected to the MCU 150, and the temperature sensor 172 is connected to the MCU 152.

Each of the MCUs can be configured to receive a temperature measurement from the corresponding temperature sensor at one or more time points. For example, the MCU can receive the temperature measurement through an inter-integrated circuit (I2C) protocol.

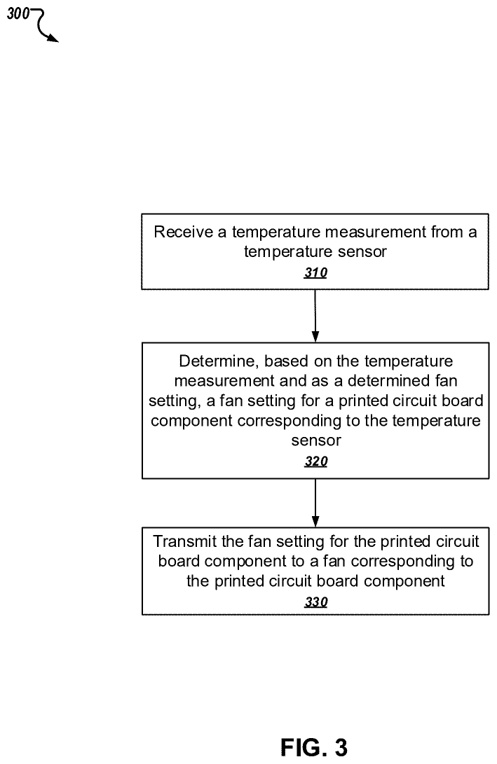

Each of the MCUs can be configured to determine a fan setting for the corresponding fan at one or more time points. For example, the MCU can determine, based on a temperature range for a corresponding PCB component for the fan, a fan setting for the corresponding fan to the corresponding fan at the one or more time points. As an example, the MCU 142 can determine a fan setting for the fan 122. Determining the fan setting for a fan is described below with reference to FIG. 3.

Each of the MCUs can be configured to transmit the determined fan setting to the corresponding fan. For example, the MCUs can transmit the determined fan settings to the corresponding fans using the I2C protocol. For example, the MCU 142 can transmit the determined fan setting to the fan 122.

The fan setting can include, for example, a fan speed. Thus, as the temperature determined by a temperature sensor increases, the MCU can determine a fan setting that is a higher fan speed. A higher fan speed can result in more airflow and more dissipation/removal of heat, which lowers the temperature. In response, as the temperature determined by the temperature sensor decreases, the MCU can determine a fan setting that is a lower fan speed. The system 100 can thus provide for automatic adjustment of a fan setting that affects the temperature of the environment of the PCB component.

Each fan of the multiple fans operates based on the instructions received from the corresponding MCU. Thus each fan can be controlled independently.

In some implementations, the system 100 can include one or more structural elements. The structural elements can be arranged on the PCB to direct airflow from fans. For example, the structural elements can be arranged to create a duct for the airflow from the fan 126 to the component 108.

In some implementations, the system 100 can include a baseboard management controller (BMC) 180. The BMC 180 serves as a backup to the MCUs for adjusting the fan settings of the fans. The BMC 180 is configured to be connected to any one or more of the temperature sensors, MCUs, or fans.

The BMC 180 can be configured to receive data indicating a status of each fan of the multiple fans. In response to receiving data indicating an inoperative status for one of the fans, the BMC 180 can determine a fan setting for the fan. The BMC 180 can transmit the determined fan setting to the fan. The system 100 can thus include a failsafe for automatically adjusting the fan settings of the fans to ensure the proper temperature of the environment of the PCB board.

In some implementations, the BMC 180 is configured to be connected to the MCUs. In these implementations, each of the MCUs can be configured to receive a temperature measurement from the BMC 180 at one or more time points. For example, each MCU can receive the temperature measurement from the corresponding temperature sensor from the BMC 180.

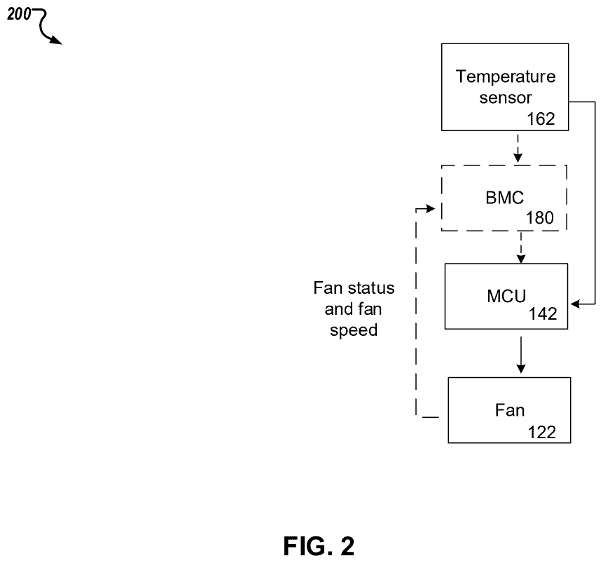

FIG. 2 is a diagram of an example process 200 for automatically adjusting a fan setting, according to an implementation of the present disclosure. The process 200 can be performed by the system 100 described above with reference to FIG. 1. In particular, FIG. 2 shows adjusting the fan setting for the fan 122.

The MCU 142 receives a temperature measurement for a time point from the temperature sensor 162. The MCU 142 determines the fan setting for the fan 122 based on the temperature measurement as described below with reference to FIG. 3. The MCU 142 transmits the fan setting for the fan 122 to the fan 122.

The BMC 180 can receive data indicating a status of the fan 122 from the fan 122. For example, the BMC 180 can receive the data through the I2C protocol. As an example, the status of the fan can be an operative status or an inoperative status. As another example, the status of the fan can include one or more fan settings for the fan, e.g., the current fan speed.

In some cases, the MCU 142 may stall. In these cases, the status of the fan 122 can be an inoperative status. The BMC 180 thus receives data indicating an inoperative status for the fan 122.

In response to receiving data indicating the inoperative status for the fan 122, the BMC 180 determines a fan setting for the fan 122. In some implementations, the BMC 180 can determine the fan setting based on temperature measurements received from a temperature sensor corresponding to the MCU 142. In some implementations, the BMC 180 can determine the fan setting to a default fan setting, e.g., 100%.

Thus, in cases where the fan 122 is inoperative due to the MCU 142 stalling, the BMC 180 can ensure that the fan setting is adjusted.

FIG. 3 is a flowchart illustrating an example of a computer-implemented method 300 for automatically adjusting a fan setting, according to an implementation of the present disclosure. For clarity of presentation, the description that follows generally describes method 300 in the context of the other figures in this description. However, it will be understood that method 300 can be performed, for example, by any system, environment, software, and hardware, or a combination of systems, environments, software, and hardware, as appropriate. In some implementations, various steps of method 300 can be run in parallel, in combination, in loops, or in any order. In some implementations, the system 100 can perform one or more, or all of the processes described in the method 300.

The method performs steps 310-330 at each of one or more time points. The time points can be, for example, at points in time that are a threshold window of time apart from each other. As an example, the threshold window of time is a fixed threshold.

At 310, a temperature measurement is received from a temperature sensor.

At 320, a fan setting for a printed circuit board component corresponding to the temperature sensor is determined based on the temperature measurement and as a determined fan setting. In some examples, the fan setting can include a fan speed. For example, the fan setting can be a percentage, e.g., 50%, 60%, or 70%, of the fastest fan speed for the fan.

To determine the fan speed, one or more threshold temperatures for the printed circuit board component can be obtained. For example, the system can maintain the one or more threshold temperatures in memory. The system can obtain the one or more threshold temperatures from the memory. In some examples, the threshold temperatures can include lower and upper bounds of an ideal operating temperature range for the printed circuit board component.

The fan speed can be determined based on the one or more threshold temperatures. For example, a determination can be made whether the temperature measurement is greater than one of the threshold temperatures. If it is determined that the temperature measurement is greater than one of the threshold temperatures, the fan speed can be adjusted to a higher fan speed. If it is determined that the temperature measurement is less than one of the threshold temperatures, the fan speed can be adjusted to a lower fan speed.

In some implementations, the higher fan speed is a default fan speed for the threshold temperature for the component. For example, the upper bound of an ideal operating temperature range for a GPU can be 85 degrees Celsius (C.). The upper bound can be a threshold temperature. For example, the default fan speed for the threshold temperature of 85 degrees C. can be 90%. The default fan speed for another threshold temperature such as 75 degrees C. can be 80%.

As another example, for a network card, the default fan speed for the threshold temperature of 50 degrees is 60%. The default fan speed for the threshold temperature of 60 degrees is 70%.

In some examples, the default fan speed for the one or more threshold temperatures can have been determined through simulation. For example, a simulation system can determine the fan speed needed to maintain the temperature at multiple threshold temperatures. The simulation system can maintain data representing the fan setting as the default fan speed. The simulation system can provide data representing the threshold temperatures and the default fan speeds to the MCU corresponding to the fan.

In some implementations, the higher fan speed is a higher fan speed relative to the current fan speed. For example, the higher fan speed can be increased over the current fan speed by a fixed speed or fixed percentage, e.g., 2% higher.

At 330, the fan setting for the printed circuit board component is transmitted to a fan corresponding to the printed circuit board component. For example, the fan setting can be transmitted to the fan through the I2C protocol.

In some examples, the method proceeds to step 310 for a next time point in the multiple time points. The method 300 can thus be performed at multiple time points to ensure proper temperature for the printed circuit board component.

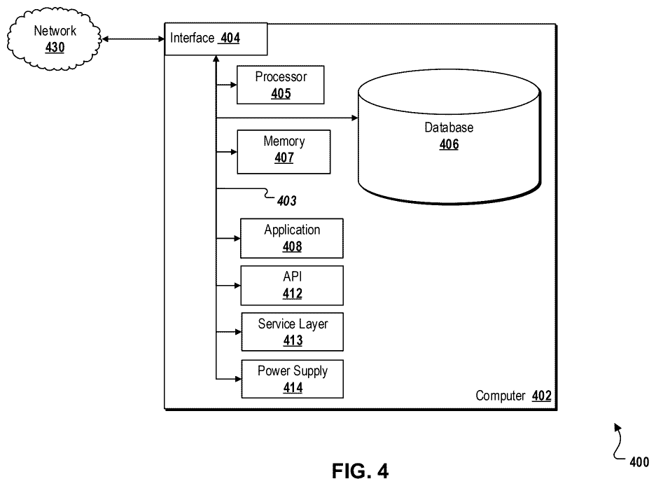

FIG. 4 is a block diagram illustrating an example of a computer-implemented System 400 used to provide computational functionalities associated with described algorithms, methods, functions, processes, flows, and procedures, according to an implementation of the present disclosure. In the illustrated implementation, computer-implemented system 400 includes a Computer 402 and a Network 430.

The illustrated Computer 402 is intended to encompass any computing device, such as a server, desktop computer, laptop/notebook computer, wireless data port, smart phone, personal data assistant (PDA), tablet computer, one or more processors within these devices, or a combination of computing devices, including physical or virtual instances of the computing device, or a combination of physical or virtual instances of the computing device. Additionally, the Computer 402 can include an input device, such as a keypad, keyboard, or touch screen, or a combination of input devices that can accept user information, and an output device that conveys information associated with the operation of the Computer 402, including digital data, visual, audio, another type of information, or a combination of types of information, on a graphical-type user interface (UI) (or GUI) or other UI.

The Computer 402 can serve in a role in a distributed computing system as, for example, a client, network component, a server, or a database or another persistency, or a combination of roles for performing the subject matter described in the present disclosure. The illustrated Computer 402 is communicably coupled with a Network 430. In some implementations, one or more components of the Computer 402 can be configured to operate within an environment, or a combination of environments, including cloud-computing, local, or global.

At a high level, the Computer 402 is an electronic computing device operable to receive, transmit, process, store, or manage data and information associated with the described subject matter. According to some implementations, the Computer 402 can also include or be communicably coupled with a server, such as an application server, e-mail server, web server, caching server, or streaming data server, or a combination of servers.

The Computer 402 can receive requests over Network 430 (for example, from a client software application executing on another Computer 402) and respond to the received requests by processing the received requests using a software application or a combination of software applications. In addition, requests can also be sent to the Computer 402 from internal users (for example, from a command console or by another internal access method), external or third-parties, or other entities, individuals, systems, or computers.

Each of the components of the Computer 402 can communicate using a System Bus 403. In some implementations, any or all of the components of the Computer 402, including hardware, software, or a combination of hardware and software, can interface over the System Bus 403 using an application programming interface (API) 412, a Service Layer 413, or a combination of the API 412 and Service Layer 413. The API 412 can include specifications for routines, data structures, and object classes. The API 412 can be either computer-language independent or dependent and refer to a complete interface, a single function, or even a set of APIs. The Service Layer 413 provides software services to the Computer 402 or other components (whether illustrated or not) that are communicably coupled to the Computer 402. The functionality of the Computer 402 can be accessible for all service consumers using the Service Layer 413. Software services, such as those provided by the Service Layer 413, provide reusable, defined functionalities through a defined interface. For example, the interface can be software written in a computing language (for example JAVA or C++) or a combination of computing languages, and providing data in a particular format (for example, extensible markup language (XML)) or a combination of formats. While illustrated as an integrated component of the Computer 402, alternative implementations can illustrate the API 412 or the Service Layer 413 as stand-alone components in relation to other components of the Computer 402 or other components (whether illustrated or not) that are communicably coupled to the Computer 402. Moreover, any or all parts of the API 412 or the Service Layer 413 can be implemented as a child or a sub-module of another software module, enterprise application, or hardware module without departing from the scope of the present disclosure.

The Computer 402 includes an Interface 404. Although illustrated as a single Interface 404, two or more Interfaces 404 can be used according to particular needs, desires, or particular implementations of the Computer 402. The Interface 404 is used by the Computer 402 for communicating with another computing system (whether illustrated or not) that is communicatively linked to the Network 430 in a distributed environment. Generally, the Interface 404 is operable to communicate with the Network 430 and includes logic encoded in software, hardware, or a combination of software and hardware. More specifically, the Interface 404 can include software supporting one or more communication protocols associated with communications such that the Network 430 or hardware of Interface 404 is operable to communicate physical signals within and outside of the illustrated Computer 402.

The Computer 402 includes a Processor 405. Although illustrated as a single Processor 405, two or more Processors 405 can be used according to particular needs, desires, or particular implementations of the Computer 402. Generally, the Processor 405 executes instructions and manipulates data to perform the operations of the Computer 402 and any algorithms, methods, functions, processes, flows, and procedures as described in the present disclosure.

The Computer 402 also includes a Database 406 that can hold data for the Computer 402, another component communicatively linked to the Network 430 (whether illustrated or not), or a combination of the Computer 402 and another component. For example, Database 506 can be an in-memory or conventional database storing data consistent with the present disclosure. In some implementations, Database 406 can be a combination of two or more different database types (for example, a hybrid in-memory and conventional database) according to particular needs, desires, or particular implementations of the Computer 402 and the described functionality. Although illustrated as a single Database 406, two or more databases of similar or differing types can be used according to particular needs, desires, or particular implementations of the Computer 402 and the described functionality. While Database 406 is illustrated as an integral component of the Computer 402, in alternative implementations, Database 406 can be external to the Computer 402. The Database 406 can hold and operate on at least any data type mentioned or any data type consistent with this disclosure.

The Computer 402 also includes a Memory 407 that can hold data for the Computer 402, another component or components communicatively linked to the Network 430 (whether illustrated or not), or a combination of the Computer 402 and another component. Memory 407 can store any data consistent with the present disclosure. In some implementations, Memory 407 can be a combination of two or more different types of memory (for example, a combination of semiconductor and magnetic storage) according to particular needs, desires, or particular implementations of the Computer 402 and the described functionality. Although illustrated as a single Memory 407, two or more Memories 407 or similar or differing types can be used according to particular needs, desires, or particular implementations of the Computer 402 and the described functionality. While Memory 407 is illustrated as an integral component of the Computer 402, in alternative implementations, Memory 407 can be external to the Computer 402.

The Application 408 is an algorithmic software engine providing functionality according to particular needs, desires, or particular implementations of the Computer 402, particularly with respect to functionality described in the present disclosure. For example, Application 408 can serve as one or more components, modules, or applications. Further, although illustrated as a single Application 408, the Application 408 can be implemented as multiple Applications 408 on the Computer 402. In addition, although illustrated as integral to the Computer 402, in alternative implementations, the Application 408 can be external to the Computer 402.

The Computer 402 can also include a Power Supply 414. The Power Supply 414 can include a rechargeable or non-rechargeable battery that can be configured to be either user- or non-user-replaceable. In some implementations, the Power Supply 414 can include power-conversion or management circuits (including recharging, standby, or another power management functionality). In some implementations, the Power Supply 414 can include a power plug to allow the Computer 402 to be plugged into a wall socket or another power source to, for example, power the Computer 402 or recharge a rechargeable battery.

There can be any number of Computers 402 associated with, or external to, a computer system containing Computer 402, each Computer 402 communicating over Network 430. Further, the term “client,” “user,” or other appropriate terminology can be used interchangeably, as appropriate, without departing from the scope of the present disclosure. Moreover, the present disclosure contemplates that many users can use one Computer 402, or that one user can use multiple computers 402.

Described implementations of the subject matter can include one or more features, alone or in combination.

For example, in a first implementation, a computer-implemented system comprises: a plurality of printed circuit board components; a plurality of fans, each fan of the plurality of fans corresponding to a printed circuit board component of the plurality of printed circuit board components; a plurality of microcontroller units (MCUs), each MCU of the plurality of MCUs configured to be connected to a corresponding fan of the plurality of fans; and a plurality of temperature sensors, wherein each temperature sensor of the plurality of temperature sensors is configured to determine a temperature measurement at one or more time points, and wherein each temperature sensor of the plurality of temperature sensors is configured to be connected to a corresponding MCU of the plurality of MCUs.

The foregoing and other described implementations can each, optionally, include one or more of the following features:
A first feature, combinable with any of the following features, wherein airflow from each fan is directed at a corresponding printed circuit board component of the plurality of printed circuit board components.
A second feature, combinable with any of the following features, wherein each MCU of the plurality of MCUs is configured to receive a temperature measurement from a corresponding temperature sensor at one or more time points through an inter-integrated circuit (I2C) protocol.
A third feature, combinable with any of the following features, wherein each MCU of the plurality of MCUs is configured to determine, based on the temperature measurement at the one or more time points and as a determined fan setting, a fan setting for a corresponding fan at the one or more time points.
A fourth feature, combinable with any of the following features, wherein the fan setting comprises a fan speed.
A fifth feature, combinable with any of the following features, wherein each MCU of the plurality of MCUs is configured to transmit the determined fan setting to a corresponding fan.
A sixth feature, combinable with any of the following features, wherein each MCU of the plurality of MCUs is configured to determine, based on a temperature range for a corresponding printed circuit board component for the fan and as a determined fan setting, a fan setting for a corresponding fan at the one or more time points.
A seventh feature, combinable with any of the following features, comprising: a baseboard management controller (BMC) configured to be connected to the plurality of temperature sensors, the plurality of MCUs, and the plurality of fans.
An eighth feature, combinable with any of the following features, wherein each MCU of the plurality of MCUs is configured to receive a temperature measurement from the BMC at one or more time points.
A ninth feature, combinable with any of the following features, wherein the BMC is configured to receive data indicating a status of each fan of the plurality of fans.
A tenth feature, combinable with any of the following features, wherein the BMC is configured to determine, in response to receiving data indicating an inoperative status for one of the plurality of fans and as a determined fan setting, a fan setting for the fan.

In a second implementation, a computer-implemented method comprises, at each of one or more time points: receiving a temperature measurement from a temperature sensor; determining, based on the temperature measurement and as a determined fan setting, a fan setting for a printed circuit board component corresponding to the temperature sensor; and transmitting the fan setting for the printed circuit board component to a fan corresponding to the printed circuit board component.

The foregoing and other described implementations can each, optionally, include one or more of the following features:
A first feature, combinable with any of the following features, wherein the fan setting comprises a fan speed.
A second feature, combinable with any of the following features, wherein determining, based on the temperature measurement and as a determined fan setting, a fan setting for a printed circuit board component corresponding to the temperature sensor, comprises: obtaining one or more threshold temperatures for the printed circuit board component; and determining, based on the one or more threshold temperatures, the fan speed.
A third feature, combinable with any of the following features, wherein determining, based on the one or more threshold temperatures, the fan speed, comprises: determining that the temperature measurement is greater than one of the threshold temperatures; and adjusting the fan speed to a higher fan speed.
A fourth feature, combinable with any of the following features, wherein determining, based on the one or more threshold temperatures, the fan speed, comprises: determining that the temperature measurement is less than one of the threshold temperatures; and adjusting the fan speed to a lower fan speed.

In a third implementation, a non-transitory, computer-readable medium storing one or more instructions executable by a computer system to perform one or more operations, comprising: receiving a temperature measurement from a temperature sensor; determining, based on the temperature measurement and as a determined fan setting, a fan setting for a printed circuit board component corresponding to the temperature sensor; and transmitting the fan setting for the printed circuit board component to a fan corresponding to the printed circuit board component.

The foregoing and other described implementations can each, optionally, include one or more of the following features:
A first feature, combinable with any of the following features, wherein the fan setting comprises a fan speed.
A second feature, combinable with any of the following features, wherein determining, based on the temperature measurement and as a determined fan setting, a fan setting for a printed circuit board component corresponding to the temperature sensor, comprises: obtaining one or more threshold temperatures for the printed circuit board component; and determining, based on the one or more threshold temperatures, the fan speed.
A third feature, combinable with any of the following features, wherein determining, based on the one or more threshold temperatures, the fan speed, comprises: determining that the temperature measurement is greater than one of the threshold temperatures; and adjusting the fan speed to a higher fan speed.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs, that is, one or more modules of computer program instructions encoded on a tangible, non-transitory, computer-readable medium for execution by, or to control the operation of, a computer or computer-implemented system. Alternatively, or additionally, the program instructions can be encoded in/on an artificially generated propagated signal, for example, a machine-generated electrical, optical, or electromagnetic signal that is generated to encode information for transmission to a receiver apparatus for execution by a computer or computer-implemented system. The computer-storage medium can be a machine-readable storage device, a machine-readable storage substrate, a random or serial access memory device, or a combination of computer-storage mediums. Configuring one or more computers means that the one or more computers have installed hardware, firmware, or software (or combinations of hardware, firmware, and software) so that when the software is executed by the one or more computers, particular computing operations are performed. The computer storage medium is not, however, a propagated signal.

The term “real-time,” “real time,” “realtime,” “real (fast) time (RFT),” “near(ly) real-time (NRT),” “quasi real-time,” or similar terms (as understood by one of ordinary skill in the art), means that an action and a response are temporally proximate such that an individual perceives the action and the response occurring substantially simultaneously. For example, the time difference for a response to display (or for an initiation of a display) of data following the individual's action to access the data can be less than 1 millisecond (ms), less than 1 second(s), or less than 5 s. While the requested data need not be displayed (or initiated for display) instantaneously, it is displayed (or initiated for display) without any intentional delay, taking into account processing limitations of a described computing system and time required to, for example, gather, accurately measure, analyze, process, store, or transmit the data.

The terms “data processing apparatus,” “computer,” “computing device,” or “electronic computer device” (or an equivalent term as understood by one of ordinary skill in the art) refer to data processing hardware and encompass all kinds of apparatuses, devices, and machines for processing data, including by way of example, a programmable processor, a computer, or multiple processors or computers. The computer can also be, or further include special-purpose logic circuitry, for example, a central processing unit (CPU), a field-programmable gate array (FPGA), or an application-specific integrated circuit (ASIC). In some implementations, the computer or computer-implemented system or special-purpose logic circuitry (or a combination of the computer or computer-implemented system and special-purpose logic circuitry) can be hardware- or software-based (or a combination of both hardware- and software-based). The computer can optionally include code that creates an execution environment for computer programs, for example, code that constitutes processor firmware, a protocol stack, a database management system, an operating system, or a combination of execution environments. The present disclosure contemplates the use of a computer or computer-implemented system with an operating system, for example LINUX, UNIX, WINDOWS, MAC OS, ANDROID, or IOS, or a combination of operating systems.

A computer program, which can also be referred to or described as a program, software, a software application, a unit, a module, a software module, a script, code, or other component can be written in any form of programming language, including compiled or interpreted languages, or declarative or procedural languages, and it can be deployed in any form, including, for example, as a stand-alone program, module, component, or subroutine, for use in a computing environment. A computer program can, but need not, correspond to a file in a file system. A program can be stored in a portion of a file that holds other programs or data, for example, one or more scripts stored in a markup language document, in a single file dedicated to the program in question, or in multiple coordinated files, for example, files that store one or more modules, sub-programs, or portions of code. A computer program can be deployed to be executed on one computer or on multiple computers that are located at one site or distributed across multiple sites and interconnected by a communication network.

While portions of the programs illustrated in the various figures can be illustrated as individual components, such as units or modules, that implement described features and functionality using various objects, methods, or other processes, the programs can instead include a number of sub-units, sub-modules, third-party services, components, libraries, and other components, as appropriate. Conversely, the features and functionality of various components can be combined into single components, as appropriate. Thresholds used to make computational determinations can be statically, dynamically, or both statically and dynamically determined.

Described methods, processes, or logic flows represent one or more examples of functionality consistent with the present disclosure and are not intended to limit the disclosure to the described or illustrated implementations, but to be accorded the widest scope consistent with described principles and features. The described methods, processes, or logic flows can be performed by one or more programmable computers executing one or more computer programs to perform functions by operating on input data and generating output data. The methods, processes, or logic flows can also be performed by, and computers can also be implemented as, special-purpose logic circuitry, for example, a CPU, an FPGA, or an ASIC.

Computers for the execution of a computer program can be based on general or special-purpose microprocessors, both, or another type of CPU. Generally, a CPU will receive instructions and data from and write to a memory. The essential elements of a computer are a CPU, for performing or executing instructions, and one or more memory devices for storing instructions and data. Generally, a computer will also include, or be operatively coupled to, receive data from or transfer data to, or both, one or more mass storage devices for storing data, for example, magnetic, magneto-optical disks, or optical disks. However, a computer need not have such devices. Moreover, a computer can be embedded in another device, for example, a mobile telephone, a personal digital assistant (PDA), a mobile audio or video player, a game console, a global positioning system (GPS) receiver, or a portable memory storage device, for example, a universal serial bus (USB) flash drive, to name just a few.

Non-transitory computer-readable media for storing computer program instructions and data can include all forms of permanent/non-permanent or volatile/non-volatile memory, media and memory devices, including by way of example semiconductor memory devices, for example, random access memory (RAM), read-only memory (ROM), phase change memory (PRAM), static random access memory (SRAM), dynamic random access memory (DRAM), erasable programmable read-only memory (EPROM), electrically erasable programmable read-only memory (EEPROM), and flash memory devices; magnetic devices, for example, tape, cartridges, cassettes, internal/removable disks; magneto-optical disks; and optical memory devices, for example, digital versatile/video disc (DVD), compact disc (CD)-ROM, DVD+/-R, DVD-RAM, DVD-ROM, high-definition/density (HD)-DVD, and BLU-RAY/BLU-RAY DISC (BD), and other optical memory technologies. The memory can store various objects or data, including caches, classes, frameworks, applications, modules, backup data, jobs, web pages, web page templates, data structures, database tables, repositories storing dynamic information, or other appropriate information including any parameters, variables, algorithms, instructions, rules, constraints, or references. Additionally, the memory can include other appropriate data, such as logs, policies, security or access data, or reporting files. The processor and the memory can be supplemented by, or incorporated in, special-purpose logic circuitry.

To provide for interaction with a user, implementations of the subject matter described in this specification can be implemented on a computer having a display device, for example, a cathode ray tube (CRT), liquid crystal display (LCD), light emitting diode (LED), or plasma monitor, for displaying information to the user and a keyboard and a pointing device, for example, a mouse, trackball, or trackpad by which the user can provide input to the computer. Input can also be provided to the computer using a touchscreen, such as a tablet computer surface with pressure sensitivity or a multi-touch screen using capacitive or electric sensing. Other types of devices can be used to interact with the user. For example, feedback provided to the user can be any form of sensory feedback (such as, visual, auditory, tactile, or a combination of feedback types). Input from the user can be received in any form, including acoustic, speech, or tactile input. In addition, a computer can interact with the user by sending documents to and receiving documents from a client computing device that is used by the user (for example, by sending web pages to a web browser on a user's mobile computing device in response to requests received from the web browser).

The term “graphical user interface (GUI) can be used in the singular or the plural to describe one or more graphical user interfaces and each of the displays of a particular graphical user interface. Therefore, a GUI can represent any graphical user interface, including but not limited to, a web browser, a touch screen, or a command line interface (CLI) that processes information and efficiently presents the information results to the user. In general, a GUI can include a number of user interface (UI) elements, some or all associated with a web browser, such as interactive fields, pull-down lists, and buttons. These and other UI elements can be related to or represent the functions of the web browser.

Implementations of the subject matter described in this specification can be implemented in a computing system that includes a back-end component, for example, as a data server, or that includes a middleware component, for example, an application server, or that includes a front-end component, for example, a client computer having a graphical user interface or a Web browser through which a user can interact with an implementation of the subject matter described in this specification, or any combination of one or more such back-end, middleware, or front-end components. The components of the system can be interconnected by any form or medium of wireline or wireless digital data communication (or a combination of data communication), for example, a communication network. Examples of communication networks include a local area network (LAN), a radio access network (RAN), a metropolitan area network (MAN), a wide area network (WAN), Worldwide Interoperability for Microwave Access (WIMAX), a wireless local area network (WLAN) using, for example, 802.11x or other protocols, all or a portion of the Internet, another communication network, or a combination of communication networks. The communication network can communicate with, for example, Internet Protocol (IP) packets, frame relay frames, Asynchronous Transfer Mode (ATM) cells, voice, video, data, or other information between network nodes.

The computing system can include clients and servers. A client and server are generally remote from each other and typically interact through a communication network. The relationship of client and server arises by virtue of computer programs running on the respective computers and having a client-server relationship to each other.

While this specification contains many specific implementation details, these should not be construed as limitations on the scope of any inventive concept or on the scope of what can be claimed, but rather as descriptions of features that can be specific to particular implementations of particular inventive concepts. Certain features that are described in this specification in the context of separate implementations can also be implemented, in combination, in a single implementation. Conversely, various features that are described in the context of a single implementation can also be implemented in multiple implementations, separately, or in any sub-combination. Moreover, although previously described features can be described as acting in certain combinations and even initially claimed as such, one or more features from a claimed combination can, in some cases, be excised from the combination, and the claimed combination can be directed to a sub-combination or variation of a sub-combination.

Particular implementations of the subject matter have been described. Other implementations, alterations, and permutations of the described implementations are within the scope of the following claims as will be apparent to those skilled in the art. While operations are depicted in the drawings or claims in a particular order, this should not be understood as requiring that such operations be performed in the particular order shown or in sequential order, or that all illustrated operations be performed (some operations can be considered optional), to achieve desirable results. In certain circumstances, multitasking or parallel processing (or a combination of multitasking and parallel processing) can be advantageous and performed as deemed appropriate.

The separation or integration of various system modules and components in the previously described implementations should not be understood as requiring such separation or integration in all implementations, and it should be understood that the described program components and systems can generally be integrated together in a single software product or packaged into multiple software products.

Accordingly, the previously described example implementations do not define or constrain the present disclosure. Other changes, substitutions, and alterations are also possible without departing from the scope of the present disclosure.

Furthermore, any claimed implementation is considered to be applicable to at least a computer-implemented method; a non-transitory, computer-readable medium storing computer-readable instructions to perform the computer-implemented method; and a computer system comprising a computer memory interoperably coupled with a hardware processor configured to perform the computer-implemented method or the instructions stored on the non-transitory, computer-readable medium.

What is claimed is:

1. A computer-implemented system comprising:
a plurality of printed circuit board components;
a plurality of fans, each fan of the plurality of fans corresponding to a printed circuit board component of the plurality of printed circuit board components;
a plurality of microcontroller units (MCUs), each MCU of the plurality of MCUs configured to be connected to a corresponding fan of the plurality of fans; and
a plurality of temperature sensors, wherein each temperature sensor of the plurality of temperature sensors is configured to determine a temperature measurement at one or more time points, and wherein each temperature sensor of the plurality of temperature sensors is configured to be connected to a corresponding MCU of the plurality of MCUs.

2. The computer-implemented system of claim 1, wherein airflow from each fan is directed at a corresponding printed circuit board component of the plurality of printed circuit board components.

3. The computer-implemented system of claim 1, wherein each MCU of the plurality of MCUs is configured to receive a temperature measurement from a corresponding temperature sensor at one or more time points through an inter-integrated circuit (I2C) protocol.

4. The computer-implemented system of claim 1, wherein each MCU of the plurality of MCUs is configured to determine, based on the temperature measurement at the one or more time points and as a determined fan setting, a fan setting for a corresponding fan at the one or more time points.

5. The computer-implemented system of claim 4, wherein the fan setting comprises a fan speed.

6. The computer-implemented system of claim 4, wherein each MCU of the plurality of MCUs is configured to transmit the determined fan setting to a corresponding fan.

7. The computer-implemented system of claim 4, wherein each MCU of the plurality of MCUs is configured to determine, based on a temperature range for a corresponding printed circuit board component for the fan and as a determined fan setting, a fan setting for a corresponding fan at the one or more time points.

8. The computer-implemented system of claim 1, comprising:
a baseboard management controller (BMC) configured to be connected to the plurality of temperature sensors, the plurality of MCUs, and the plurality of fans.

9. The computer-implemented system of claim 8, wherein each MCU of the plurality of MCUs is configured to receive a temperature measurement from the BMC at one or more time points.

10. The computer-implemented system of claim 8, wherein the BMC is configured to receive data indicating a status of each fan of the plurality of fans.

11. The computer-implemented system of claim 10, wherein the BMC is configured to determine, in response to receiving data indicating an inoperative status for one of the plurality of fans and as a determined fan setting, a fan setting for the fan.

12. A computer-implemented method comprising, at each of one or more time points:
receiving a temperature measurement from a temperature sensor;
determining, based on the temperature measurement and as a determined fan setting, a fan setting for a printed circuit board component corresponding to the temperature sensor; and
transmitting the fan setting for the printed circuit board component to a fan corresponding to the printed circuit board component.

13. The computer-implemented method of claim 12, wherein the fan setting comprises a fan speed.

14. The computer-implemented method of claim 13, wherein determining, based on the temperature measurement and as a determined fan setting, a fan setting for a printed circuit board component corresponding to the temperature sensor, comprises:
obtaining one or more threshold temperatures for the printed circuit board component; and
determining, based on the one or more threshold temperatures, the fan speed.

15. The computer-implemented method of claim 14, wherein determining, based on the one or more threshold temperatures, the fan speed, comprises:
determining that the temperature measurement is greater than one of the threshold temperatures; and
adjusting the fan speed to a higher fan speed.

16. The computer-implemented method of claim 14, wherein determining, based on the one or more threshold temperatures, the fan speed, comprises:
determining that the temperature measurement is less than one of the threshold temperatures; and
adjusting the fan speed to a lower fan speed.

17. A non-transitory, computer-readable medium storing one or more instructions executable by a computer system to perform one or more operations, comprising:
receiving a temperature measurement from a temperature sensor;
determining, based on the temperature measurement and as a determined fan setting, a fan setting for a printed circuit board component corresponding to the temperature sensor; and
transmitting the fan setting for the printed circuit board component to a fan corresponding to the printed circuit board component.

18. The non-transitory, computer-readable medium of claim 17, wherein the fan setting comprises a fan speed.

19. The non-transitory, computer-readable medium of claim 18, wherein determining, based on the temperature measurement and as a determined fan setting, a fan setting for a printed circuit board component corresponding to the temperature sensor, comprises:
obtaining one or more threshold temperatures for the printed circuit board component; and
determining, based on the one or more threshold temperatures, the fan speed.

20. The non-transitory, computer-readable medium of claim 19, wherein determining, based on the one or more threshold temperatures, the fan speed, comprises:
determining that the temperature measurement is greater than one of the threshold temperatures; and
adjusting the fan speed to a higher fan speed.
